(19) United States
(12) Patent Application Publication
(10) Pub. No.: US 2010/0232213 A1
(43) Pub. Date: Sep. 16, 2010

(54) CONTROL SIGNAL TRANSMITTING SYSTEM OF A SEMICONDUCTOR DEVICE

(76) Inventors: Hyong-Ryol Hwang, Seoul (KR); Chi-Sung Oh, Gyeonggi-do (KR); Sang-Kyu Kang, Gyeonggi-do (KR)

Correspondence Address: F. CHAU & ASSOCIATES, LLC, 130 WOODBURY ROAD, WOODBURY, NY, 11797, US

(21) Appl. No.: 12/711,586

(22) Filed: Feb. 24, 2010

(30) Foreign Application Priority Data
Mar. 12, 2009 (KR) 10-2009-0021068

(51) Int. Cl. G11C 11/24; G11C 7/00; G11C 8/18

(52) U.S. Cl. 365/149; 365/203; 365/233.1

(57) ABSTRACT

Exemplary embodiments relate to a control signal driving device of a semiconductor device, including: a bus line; a converter receiving a first periodic control signal having the period (frequency) of a clock signal, converting the first periodic control signal into a converted control signal that has twice the period (half the frequency) of the clock signal, and outputting the converted control signal to the bus line; and a restoring unit connected to the opposite end of the bus line and receiving the converted control signal and restoring the converted control signal back into the first periodic control signal.

### CROSS-REFERENCE TO RELATED APPLICATIONS

This U.S. non-provisional patent application claims the benefit, under 35 U.S.C. §119, of Korean Patent Application 10-2009-0021068, filed on Mar. 12, 2009, in the Korean Intellectual Property Office, the entire contents of which are incorporated by reference herein.

### BACKGROUND

1. Field of the Invention

Exemplary embodiments of the present invention relate to a semiconductor device, and more particularly, to a control signal driving device of a semiconductor memory device.

2. Description of the Related Art

In recent years, the speed and the degree of miniaturization of semiconductor memory devices, such as dynamic random access memories (DRAMS), have increased continuously to meet consumer demands. DRAMs store information in arrays of memory cells that include capacitors formed in integrated circuits on a chip. The DRAM devices having one access transistor and one storage capacitor in each memory cell are generally used as the main memory of an electronic system.

A dynamic random access memory device 10 (hereinafter, referred to as a DRAM) shown in FIG. 1 serves as a main memory in a general data processing system and is connected to a microprocessing unit (MPU) 2 through a first system bus B1. The microprocessing unit 2 of the data processing system is connected to a flash memory 4 through a second system bus B5 and performs a predetermined processing operation according to the executable program stored in the flash memory. In addition, the microprocessing unit 2 controls a driving unit 6 through a control bus B2, if necessary. When controlling the driving unit 6, the microprocessing unit 2 performs a data access operation of writing data to the memory cells of the DRAM 10 and reading the written data from the memory cells for each processing operation.

During the data access operation of the DRAM 10, various control signals are generated and transmitted to the DRAM 10 in order to read or write data. For example, to drive a sense amplifier in the DRAM 10, a sense amplifier enable signal is generated and transmitted to the sense amplifier. To drive a precharge circuit in the DRAM 10, a precharge control signal is generated and transmitted to the precharge circuit.

Among various control signals, clock-based signals that are generated in response to a clock and then transmitted to the DRAM 10 are toggled to correspond to a clock cycle. FIG. 5 is a diagram illustrating a bus line L10 provided in the transmission path of the clock-based signals. The bus line L10 may have a length of about 12000 microns (μm). Therefore, capacitative line loading is relatively large. Therefore, a relatively large amount of power is consumed to transmit the clock based signals.

It has been estimated that in a DRAM having a 2-Gbit storage capacity, the amount of power consumed charging and discharging the bus line L10 when the clock-based signals are transmitted is about 5% of the total amount of power consumed during a read/write operation.

The performance of a mobile oriented semiconductor device is improved when the amount of power consumed when the clock-based signals are transmitted is reduced.

### SUMMARY OF THE INVENTION

Exemplary embodiments of the invention provide a control signal transmitting system of a semiconductor device capable of reducing the power consumption of control signal transmission in a semiconductor memory device. The control signal transmitting system shown in FIG. 7 reduces the amount of power consumed charging and discharging the bus line L10 when the clock-based (periodic) control signals are transmitted.

Exemplary embodiments also provide a control signal transmitting system of a semiconductor device capable of reducing power required to transmit clock-based signals.

Exemplary embodiments also provide a semiconductor memory device capable of minimizing or reducing a read or write operation current.

Exemplary embodiments also provide a DRAM capable of reducing the transmission current of a clock-based control signal.

An aspect of the invention provides a control signal transmitting system of a semiconductor device including: a bus line; a converter receiving a first periodic control signal based on a clock signal and having the same period as the clock signal, converting the first periodic control signal into a converted control signal that has a period two times the period of the clock signal, and outputting the converted control signal to the bus line; and a restoring unit connected to the bus line, receiving the converted control signal, and restoring the first control signal from the converted control signal.

The converter may be an edge-triggered counter. The restoring unit may include first and second auto pulse generators. The first auto pulse generator is configured to output a first pulse of the restored first control signal in response to a rising edge of the converted signal. The second auto pulse generator is configured to output a second pulse of the restored first control signal in response to a falling edge of the converted signal.

The first control signal may be a sense amplifier control signal or a precharge control signal.

Another aspect of the invention provides a semiconductor memory device including: a memory cell array including a plurality of memory cells arranged in a matrix, each memory cell having one access transistor and one storage capacitor; a bit line sense amplifier connected to a bit line pair connected to the memory cells; a local input/output line sense amplifier connected between a global input/output line pair and a local input/output line pair; a column selecting unit operatively connecting a selected bit line pair and the local input/output line pair in response to a column selection signal; a local input/output line precharge unit precharging the local input/output line pair during a period for which the column selection signal is deactivated; a converter receiving a first sense amplifier control signal based on a clock signal, converting the first sense amplifier control signal into a converted control signal that has a period two times the period of the clock signal, and outputting the converted control signal to a signal line; and a restoring unit connected to the signal line (opposite the converter), receiving the converted control signal, and restoring the first sense amplifier control signal from the converted control signal.

The converter may be a positive edge-triggered counter. The restoring unit may include a first auto pulse generator (including a plurality of inverters and a NAND gate) configured to generate a first pulse of the restored first sense amplifier control signal in response to a rising edge of the converted control signal. The restoring unit may further include a second auto pulse generator (including a plurality of inverters and a NAND gate) configured to generate a second pulse of the restored first sense amplifier control signal in response to a falling edge of the converted control signal.

The first sense amplifier control signal may be a sense amplifier control signal for controlling a local or global sense amplifier or a precharge control signal for precharging the local or global input/output line pair.

It is possible to reduce the power required to transmit clock-based signals according to the above-mentioned exemplary embodiments of the invention.

Exemplary embodiments will be described more fully with reference to the accompanying drawings.

Specific structural and functional details disclosed herein are merely representative for purposes of describing exemplary embodiments. Exemplary embodiments may, however, may be embodied in many alternate forms and should not be construed as limited to only the embodiments set forth herein.

Accordingly, while exemplary embodiments are capable of various modifications and alternative forms, embodiments thereof are shown by way of example in the drawings and will herein be described in detail. It should be understood, however, that there is no intent to limit the invention to the particular forms disclosed, but on the contrary, to the claims cover all modifications, equivalents, and alternatives of the exemplary embodiments falling within the scope of the claims.

It will be understood that, although the terms first, second and third may be used herein to describe various elements, these elements should not be limited by these terms. These terms are only used to distinguish one element from another. For example, a first element could be termed a second element, and, similarly, a second element could be termed a first element, without departing from the scope of exemplary embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of exemplary embodiments. As used herein, the singular forms “a”, “an” and “the” are intended to include the plural forms as well, unless the context clearly indicates otherwise.

Unless otherwise defined, all terms (including technical and scientific terms) used herein have the same meaning as commonly understood by one of ordinary skill in the art to which the exemplary embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a control signal driving device of a semiconductor device capable of reducing power required to transmit clock-based signals according to an exemplary embodiment of the invention will be described with reference to the accompanying drawings. Like numbers refer to like elements throughout the description of the figures.

### BRIEF DESCRIPTION OF THE DRAWINGS

The above and other features will become more apparent by describing in detail exemplary embodiments thereof with reference to the attached drawings in which:

FIG. 1 is a block diagram of a related art data processing system that can be improved by incorporating the control signal transmitting system of FIG. 7 within the DRAM 10 according to an exemplary embodiment of the invention;

FIG. 2 is a block diagram of the DRAM 10 in FIG. 1;

FIG. 3 is a circuit and block diagram of the read path circuit 16 in FIG. 2;

FIG. 4 is a layout diagram of a DRAM chip illustrating the transmission path of a control signal shown in FIG. 3;

FIG. 5 is a diagram illustrating the connection of a bus line provided in the transmission path shown in FIG. 4;

FIG. 6 is a timing diagram illustrating the relationship among input/output signals shown in FIG. 5;

FIG. 7 is a block diagram of a control signal driving device of a semiconductor device according to an exemplary embodiment of the invention;

FIG. 8 is a timing chart illustrating the operation of the control signal driving device shown in FIG. 7;

FIG. 9 is a detailed circuit diagram of an example of the converter in FIG. 7; and

FIG. 10 is a detailed circuit diagram of an example of the restoring unit in FIG. 7.

### DETAILED DESCRIPTION OF EXEMPLARY EMBODIMENTS OF THE INVENTION

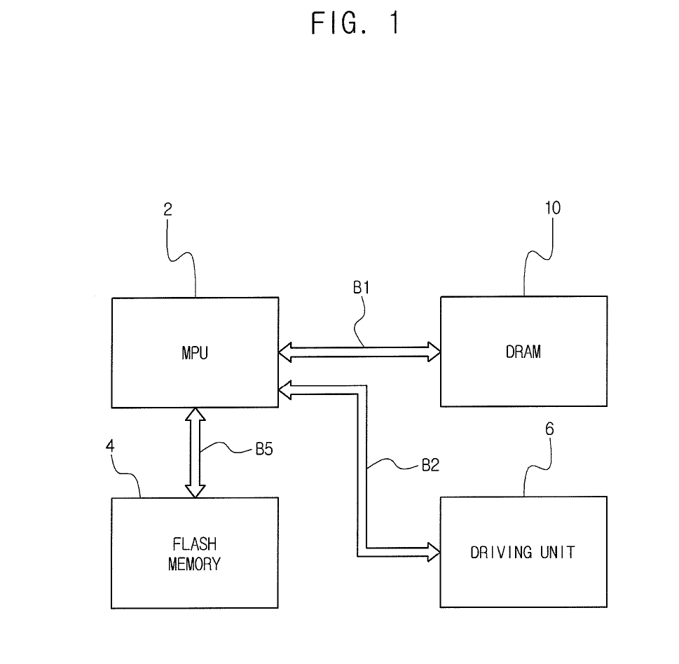

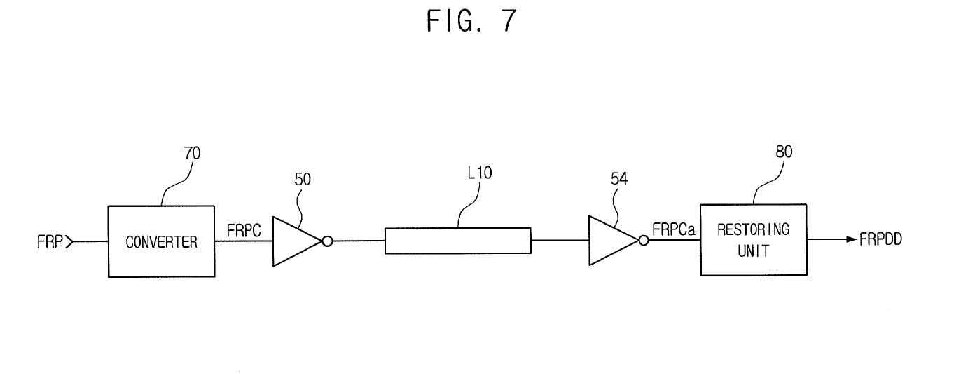

FIG. 1 is a block diagram of a related art data processing system that can be improved by incorporating the control signal transmitting system of FIG. 7 within the DRAM 10 according to an exemplary embodiment of the invention. The DRAM 10 in the data processing system of FIG. 1 will consume less power if it incorporates the control signal transmitting system of FIG. 7.

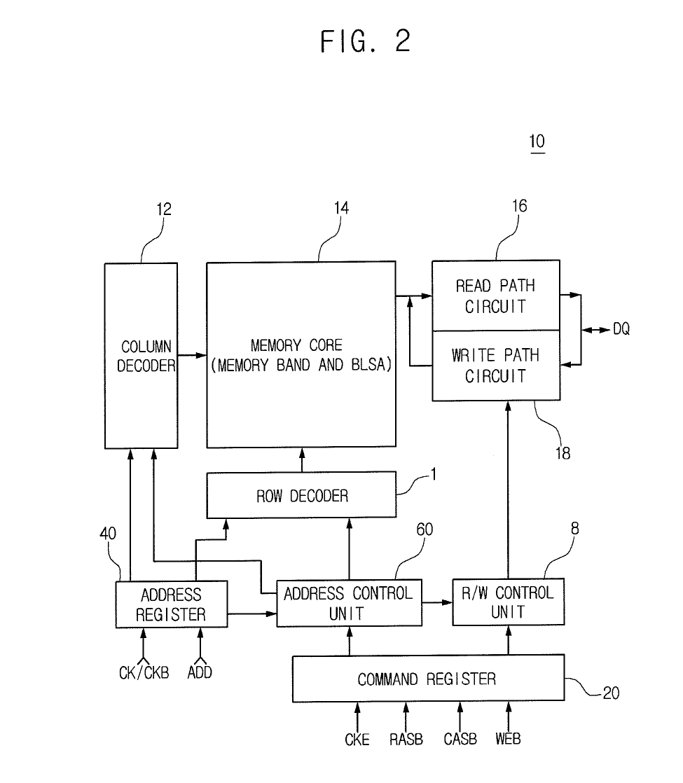

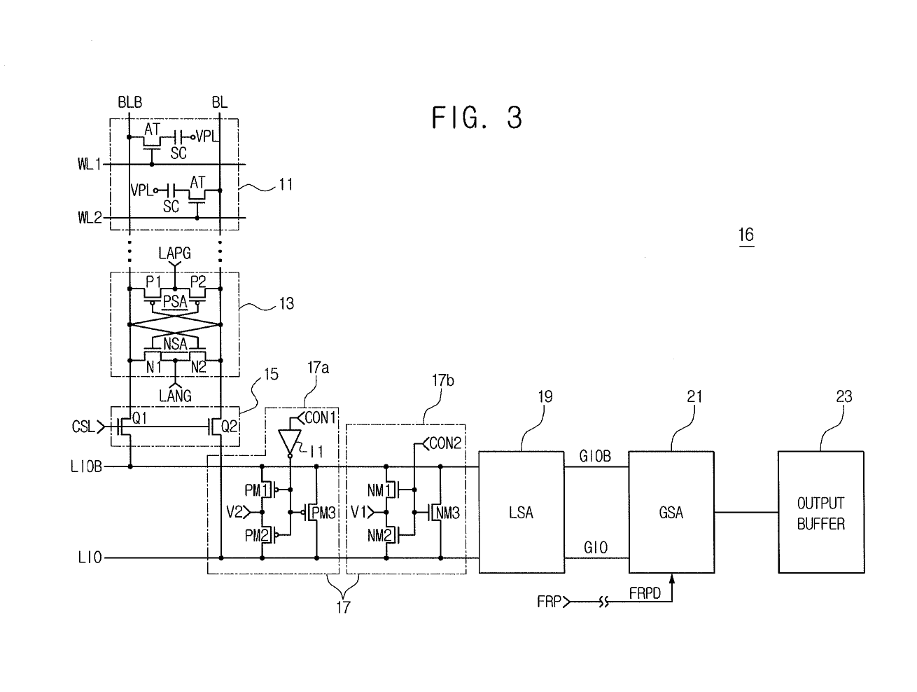

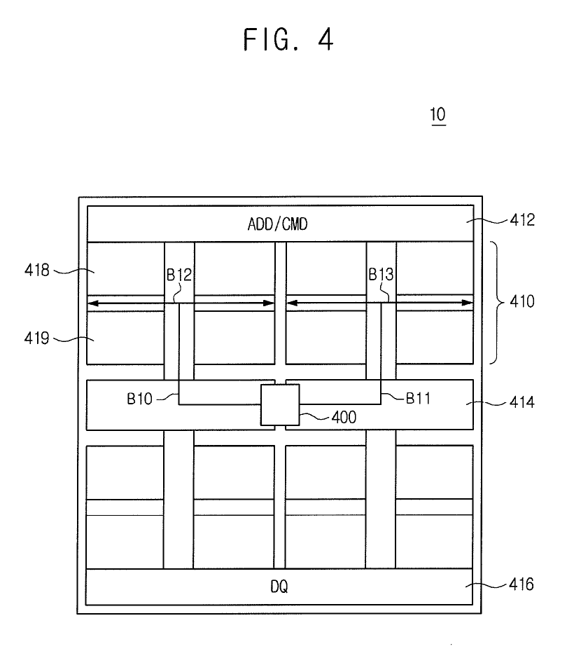

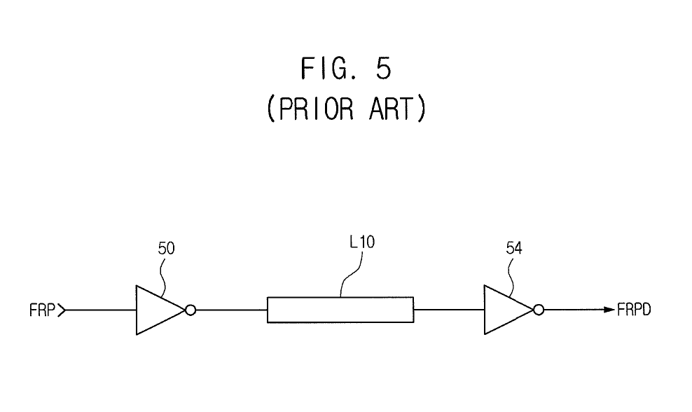

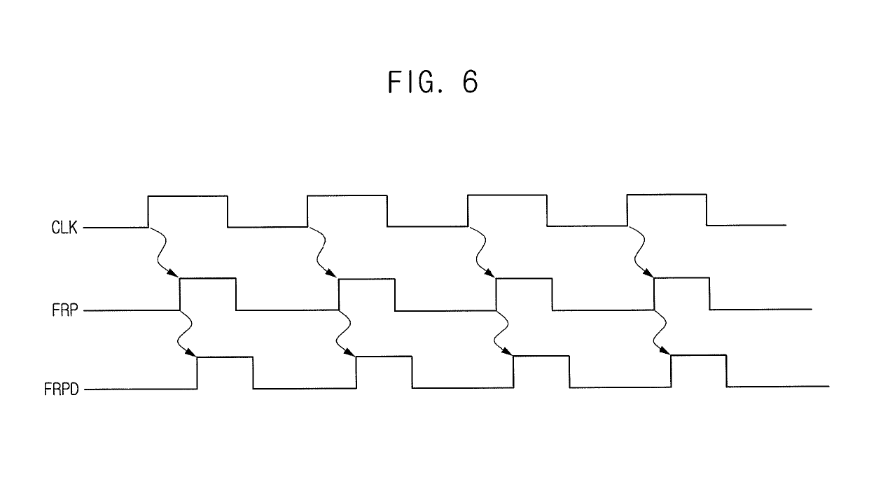

FIG. 2 is a block diagram of the DRAM shown in FIG. 1. FIG. 3 is a diagram illustrating an example of the read path circuit 16 shown in FIG. 2. FIG. 4 is a layout diagram of a DRAM chip implementing the DRAM 10 in FIG. 1. FIG. 4 illustrates a transmission path of a control signal shown in FIG. 3. FIG. 5 is a diagram illustrating the connection of a bus line provided in the transmission path shown in FIG. 4. FIG. 6 is a timing diagram of the input/output signals of the transmission path in FIG. 5.

FIG. 2 is a block diagram of the DRAM 10 illustrating the wiring relationship among general functional blocks of the DRAM 10 to which an exemplary embodiment of the invention may be applied. Referring to FIG. 2, the DRAM 10 includes a command register 20, an address register 40, an address control unit 60, a read/write control unit 8, a row decoder 1, a column decoder 12, a memory core 14, a read path circuit 16, and a write path circuit 18.

The command register 20 receives a clock enable signal CKE, a row address strobe signal RASB, a column address strobe signal CASB, and a write enable signal WEB and outputs a command signal to the address control unit 60 and the read/write control unit 8.

The address register 40 stores an applied address ADD in response to a clock CK/CKB and allocates the address ADD as a row address and a column address to the row decoder 1 and the column decoder 12, respectively.

Referring to FIGS. 2 & 3, the memory core 14 includes a bit line sense amplifier (reference numeral 13 in FIG. 3) connected to a bit line pair BL, BLB (in FIG. 3) and a memory cell array (reference numeral 11 in FIG. 3) including a plurality of memory banks in which memory cells MC each having one access transistor AT and one storage capacitor SC are arranged in a matrix so as to correspond to intersections of word lines (e.g., WL1, WL2) and bit lines (e.g., BLB, BL).

The address control unit 60 generates addresses for data access and controls a refresh operation for retaining data stored in the memory cells.

The row decoder 1 is connected to the address control unit 60 and the memory core 14 and performs row address decoding to activate a selected word line WL. The column decoder 12 receives a column address and outputs a column selection signal for selecting the bit lines BL connected to the memory cells of the memory core 14.

The read path circuit 16 and the write path circuit 18 of the data path circuit include a local input/output line precharge and equalizing unit 17, a local input/output line sense amplifier 19, a global input/output line sense amplifier 21, and an output buffer 23, as shown in FIG. 3. In addition, the read path circuit 16 and the write path circuit 18 further include a data input buffer (not shown) and a global/local input/output line driver (not shown).

Referring to FIG. 3, the read path circuit 16 of the DRAM includes the local input/output line precharge and equalizing unit 17, the local input/output line sense amplifier 19, the global input/output line sense amplifier 21, and the output buffer 23. The read path circuit 16 of the DRAM is connected to the memory core 14 shown in FIG. 2 that includes the memory cell array 11, and includes the bit line sense amplifier 13, and a column selecting unit 15.

As shown in FIG. 3, each the memory cell in the memory cell array 11 includes one access transistor AT and one storage capacitor SC. Word lines WL1 and WL2 are connected to the gates of the access transistors AT of the memory cells. A bit line pair including a bit line BL and a complementary bit line BLB is connected to the drain/source of the individual access transistors AT. The bit line sense amplifier 13 is connected to the bit line pair. When data stored in a selected memory cell of the memory cell array 11 appears as a voltage difference between the pair of the bit lines BL and BLB during a read operation, the bit line sense amplifier 13 senses and amplifies the voltage difference.

The column selecting unit 15 is a portion of a multiplexer that operatively connects the selected pair of the bit lines BL and BLB and a pair of local input/output lines LIO and LIOB connected to the local input/output line sense amplifier 19 in response to a column selection signal CSL. Then, during the read operation, the sensed and amplified result of data on the pair of the bit lines BL and BLB is transmitted to the pair of the local input/output lines LIO and LIOB.

Before a read or write operation is performed on the memory cell, (i.e., before the word line is activated), a half power supply voltage precharge and equalizing unit 17b precharges the pair of the local input/output lines LIO and LIOB with half the power supply voltage level VBL. The control signal CON2 is applied at a high level when the word line is in an inactive state, and a voltage V1 applied to a common drain connection node of NMOS transistors NM1 and NM2 has half the power supply voltage level VBL (=½ VINTA).

The local input/output line precharge unit 17a of the local input/output line precharge and equalizing unit 17 precharges the pair of the local input/output lines LIO and LIOB with a voltage having the same level as a cell array operation voltage VINTA during the period for which the word line is active and the column selection signal CSL is inactive in the active mode. The control signal CON1 is applied at a high level when the word line is in an active state, and a voltage V2 applied to a common source connection node of PMOS transistors PM1 and PM2 has the same level as the cell array operation voltage VINTA.

The PMOS transistors PM1 and PM2 are related to a precharge operation and the PMOS transistor PM3 is related to an equalizing operation.

During the read operation, the local input/output line sense amplifier 19 senses and amplifies the data of the memory cell transmitted to the pair of the local input/output lines LIO and LIOB and outputs the amplified data to the global input/output lines GIO and GIOB. The global input/output line sense amplifier 21 is enabled by a received control signal FRPD, finally senses and amplifies the data of the memory cell transmitted to the global input/output lines GIO and GIOB, and outputs the amplified data to the output buffer 23. The first control signal FRP, received by the global input/output line sense amplifier 21 as FRPD, has a periodicity that corresponds to the clock signal.

In FIG. 3, the local input/output line precharge and equalizing unit 17 includes the local input/output line precharge unit 17a and the half power supply voltage precharge and equalizing unit 17b in order to increase the sensing speed of the local input/output line sense amplifier 19 connected to the pair of the local input/output lines LIO and LIOB. For example, when the pair of the local input/output lines LIO and LIOB is precharged with a first level VBL while having the completely amplified level VINTA (=VSS), the operation of precharging the pair of the local input/output lines LIO and LIOB may serve as a noise source that changes the first level VBL. The noise source has an adverse effect on a circuit for generating a voltage with the first level VBL, which results in a reduction in the sensing efficiency of memory cell data.

Therefore, before a read or write operation is performed on the memory cell, before the active mode starts, the pair of the local input/output lines LIO and LIOB is precharged with a voltage having the same level VBL as that of the bit line precharge voltage. Then, when the word line is enabled and the active mode starts, the pair of the local input/output lines LIO and LIOB is precharged with the same voltage as the cell array operation voltage VINTA. Then, when the active mode ends, the pair of the local input/output lines LIO and LIOB is precharged with a voltage having the same level VBL as that of the bit line precharge voltage.

In a general DRAM, the precharge level of a local input/output line pair is equal to that of a bit line sensing voltage. Since the level of the bit line sensing voltage means the internal power supply voltage of the memory cell array, the local input/output line pair is precharged with the internal power supply voltage. However, only one of a pair of two local input/output lines is pulled down to the ground (GND) when the local line sensing operation is performed, unlike a bit line sensing method in which the local input/output lines are precharged with half of the level of the power supply voltage and are then pulled up to VDD or pulled down to GND. Therefore, in the local line sensing method, when the level of the voltage used is not optimized, a large amount of current is unnecessarily consumed by the local input/output line sense amplifier, as compared to the bit line sensing method. The current consumption results in an increase in power consumption, which causes performance deterioration when the DRAM is used in a portable electronic apparatus.

In addition, it is necessary to reduce the amount of current required to transmit signals, such as the clock-based (periodic) control signal FRP (transmitted as FRP and received as FRPD) shown in FIG. 3, in order to reduce the amount of current consumed during a read or write operation.

FIG. 4 illustrates the transmission path of the control signal in a DRAM chip. A signal generator 400 generates signals such as the control signal FRP, and is located in a peripheral circuit region 414 of a DRAM chip. The control signal is transmitted to sub array blocks 418 and 419 of a bank 410 of sub array blocks through buses B10, B11, B12, and B13, which are transmission paths. In FIG. 4, regions 412 and 416 indicate “peripheral” circuit regions in which address/command buffers and an output buffer are arranged respectively. The “peripheral” circuit regions 412 and 416 are peripheral to the arrays (e.g., 418, 419) of memory cells.

FIG. 5 shows one conventional bus line that is conventionally used to implement the transmission path (bus) B10 shown in FIG. 4. FIG. 5 shows the connection of a conventional bus line conventionally used to implement a transmission path shown in FIG. 4.

Referring to FIG. 5, a first control signal FRP that has a periodicity that corresponds to the clock signal is applied to the global input/output line sense amplifier 21 shown in FIG. 3 through a bus line L10 arranged between drivers 50 and 54. The periodic signal applied to the global input/output line sense amplifier 21 is a delayed signal FRPD that is the first control signal FRP delayed by a delay amount corresponding to the delay through bus line L10. The bus line L10 may have a length of about 12000 microns (μm). Therefore, capacitive line loading is relatively large.

FIG. 6 shows the waveform of the first control signal FRP and the waveform of the delayed first control signal FRPD received through the bus line L10. The first control signal FRP is a clock-based (periodic) signal that is in sync with the rising edge of the clock CLK.

When the first control signal FRP is transmitted through the bus line L10 shown in FIG. 5 that has a large amount of capacitive line loading in response to the clock CLK, toggling needs to be performed for every clock cycle. As a result, a large amount of current is consumed charging and discharging the bus line L10.

Therefore, in the exemplary embodiment of the invention, a control signal transmitting system shown in FIG. 7 is provided that reduces the amount of power consumed when the clock-based (periodic) control signals are transmitted and that improves the energy efficiency of a mobile oriented (e.g., battery powered) semiconductor device.

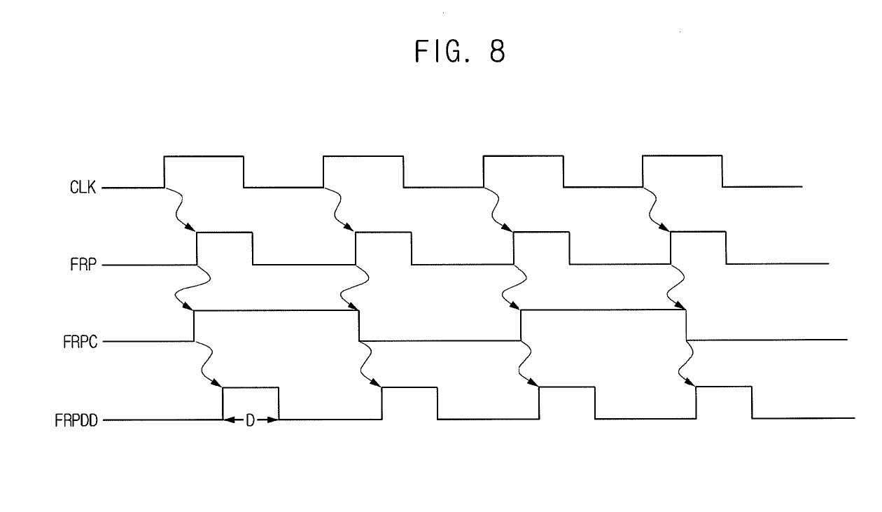

FIG. 7 is a block diagram a control signal transmitting system of a semiconductor device according to the exemplary embodiment of the invention, and FIG. 8 is a timing chart illustrating the operation of the control signal transmitting system shown in FIG. 7.

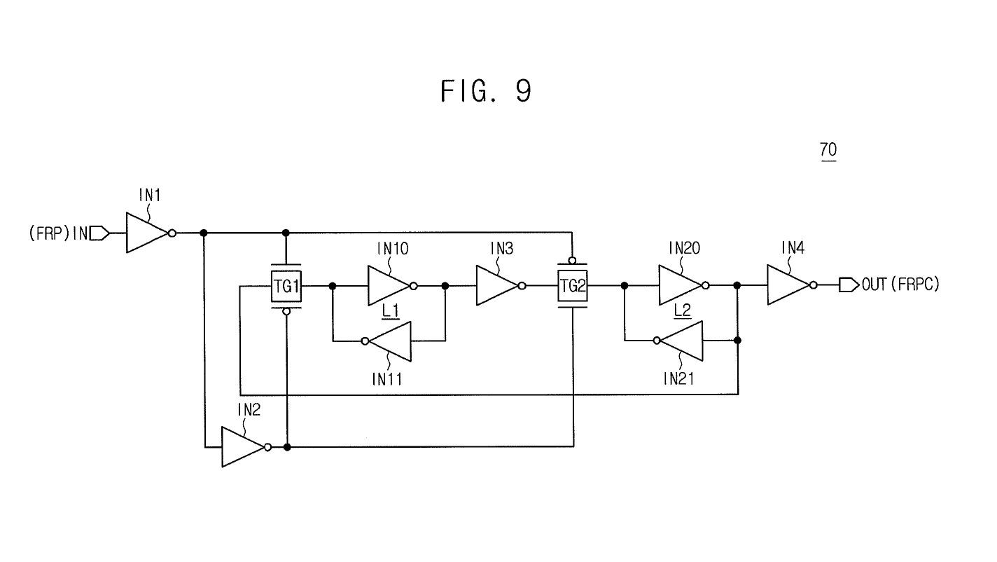

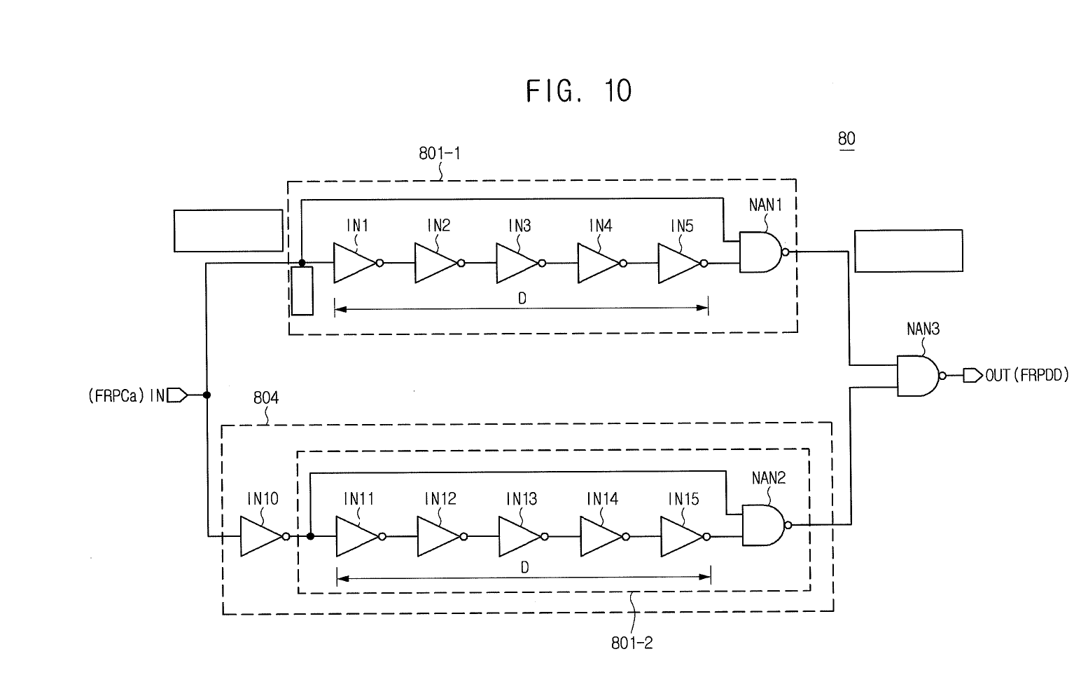

FIG. 9 is a detailed circuit diagram illustrating an example of a converter 70 in the system of FIG. 7, and FIG. 10 is a detailed circuit diagram of an example of a restoring unit in the system of FIG. 7.

Referring to FIG. 7, the control signal transmitting system includes the bus line L10, a converter 70 that receives the first control signal FRP responding to the clock signal, converts the first control signal into a converted control signal FRPC having a period that is two times the period of the clock signal, and outputs the converted control signal FRPC to the bus line L10, and a restoring unit 80 that is connected to the opposite end of the bus line L10, receives the converted control signal FRPC, and restores the first control signal from the converted control signal FRPC. In FIG. 7, the drivers 50 and 54 serving as signal relay units are connected to the bus line L10, similar to the structure shown in FIG. 5. In various alternative embodiments of the invention, the function of one or both of the drivers 50 and 54 may be incorporated in the circuits of the converter 70 and the restoring unit 80, respectively. For example, one of inverters 1N4 and IN20 in FIG. 9 may be modified to perform the function of driver 50.

Referring to the timing shown in FIG. 8, since the first control signal FRP responds to the rising edge of the clock signal CLK, the first control signal FRP has the same period as the clock signal CLK. Therefore, the number of times the first control signal FRP is toggled is equal to the number of rising edges of the clock signal CLK. In the exemplary embodiment of the invention, the converter 70 is used to reduce by half the number of times a transmission signal is toggled.

Thus, the number of times the converted control signal FRPC output from the converter 70 is toggled is half of the number of times the first control signal FRP is toggled. For example, when the first control signal FRP is toggled 500 times, the converted control signal FRPC is toggled only 250 times.

When the converted control signal FRPC is applied to the bus line L10 through the driver 50, the number of times the converted control signal FRPC is toggled is reduced to half the number of times the first control signal FRP is toggled. As a result, current consumption is reduced by a value corresponding to the reduced number of toggles.

The gain of the current consumed when the clock-based signal was transmitted was examined in a DRAM having a 2-Gbit storage capacity. As a result of the examination, the gain of the current per toggle was about 250 microamperes (μA). Therefore, when the exemplary embodiment of the invention is applied to the transmission of clock-based signals, such as the first control signal FRP, input/output precharge control signals, and sense amplifier control signals IOPRB, LIOPRB, and PLSAEN, a current is reduced by about 1.0 mA. This current reduction is desirable in portable electronic apparatuses.

The converted control signal FRPC is applied as a delay signal FRPCa to the restoring unit 80 through the driver 54. The restoring unit 80 receives the periodic converted control signal FRPC and restores, from the periodic converted control signal FRPC, a periodic signal FRPDD that has the same period as the first control signal FRP and has a pulse width equal to a delay amount D. The periodic signal FRPDD generated with the timing shown in FIG. 8 is applied to the global input/output line sense amplifier 21 shown in FIG. 3.

In FIG. 7, the first control signal FRP is applied as the sense amplifier control signal. However, the first control signal FRP may be applied as a precharge control signal to the precharge unit.

In an exemplary embodiment of the invention, the converter 70 is a positive edge-triggered counter as shown in FIG. 9, and the restoring unit 80 includes a matching pair of auto pulse generators as shown in FIG. 10.

FIG. 9 is a detailed circuit diagram illustrating an example of the converter shown in FIG. 7, and FIG. 10 is a detailed circuit diagram illustrating an example of the restoring unit 80 shown in FIG. 7.

Referring to FIG. 9 illustrating an example of the converter 70 shown in FIG. 7, a positive edge-triggered counter is implemented with two flip-flop latches. The counter includes a plurality of inverters IN1, IN2, IN3, IN4, IN10, IN11, IN20, and IN21 and a plurality of transmission gates TG1 and TG2.

The transmission gate TG2 passes a signal when an input IN is at a high level, and the transmission gate TG1 passes a signal when the input IN is at a low level. The inverters IN10 and IN11 form a first latch L1, and the inverters IN20 and IN21 form a second latch L2. The counter having the above-mentioned structure outputs the converted control signal FRPC having a waveform as shown in FIG. 8 to terminal OUT in response to only the rising edge where the input IN transitions to a high level. Therefore, the counter serves as a positive edge-triggered counter, and thus as a frequency divider.

Referring to FIG. 10, the restoring unit 80 shown in FIG. 7, includes a first auto pulse generator 801-1 and a second auto pulse generator 801-2 (804). The first auto pulse generator 801-1 is constructed the same as the second auto pulse generator 801-2. Each of the first and second auto pulse generators 801-1, 801-2 includes the same number and type (size) of inverters. (IN1 to IN5 and IN11 to 1N15) and a NAND gate (NAN1, NAN2). The first auto pulse generator is configured to generate a first pulse in response to a rising edge of the converted signal FRPC. The second auto pulse generator 804 may be deemed to include an input signal inverter IN10 so that the second auto pulse generator outputs a pulse in response to a falling edge of the input signal received at input signal inverter IN10. The second auto pulse generator is configured to generate a second pulse in response to a falling edge of the converted signal FRPC. The restoring unit 80 shown in FIG. 7, further includes a combinatorial logic circuit (NAND-gate NAN3) configured to combine the pulses output by the first and second auto pulse generators 801-1, 801-2 into a periodic pulse train having half the period (twice the frequency) of pulses from either one of the first and second auto pulse generators 801-1, 801-2.

In FIG. 10, the delay amount D through the inverters IN1 to IN5 of the first auto pulse generator corresponds to the pulse width D shown in FIG. 8. The delay amount through the inverters IN11 to IN15 of the second auto pulse generator is preferably equal to D as shown in FIG. 8, so that the pulse width of all pulses output by the restoring unit 80 are equal. Therefore, when the number of inverters in each string is decreased or increased, the pulse width D is decreased or increased, respectively. Since the principles of the operation of the auto pulse generators shown in FIG. 10 are known to persons skilled in this field, a detailed description thereof will be omitted.

According to the exemplary embodiment of the invention, the amount of current consumed when the clock-based signals are transmitted is reduced, and the amount of power consumed during a read or write operation is reduced.

While the exemplary embodiments of the invention have been shown and described with reference to the drawings, it will be understood by one of ordinary skill in the art that various changes in form and details may be made therein without departing from the spirit and scope of the exemplary embodiments as defined by the following claims. For example, the detailed circuit structure of the converter or the restoring unit may be changed without departing from the scope and spirit of the invention and the number of times the converter is toggled may be reduced to quarter or one-eighth.

In the above-described embodiment of the invention, the DRAM 10 is given as an example, but the invention may be applied to other volatile memories, such as pseudo SRAMs.

What is claimed is:

1. A signal transmitting system of a semiconductor device, comprising:
a bus line;
a converter receiving a first periodic signal that has the period of a first clock signal, converting the first periodic signal into a converted signal that has a period two times the period of the first clock signal, and outputting the converted signal to the bus line; and
a restoring unit connected to the bus line, receiving the converted signal, and restoring the first periodic signal from the converted signal.

2. The signal transmitting system of claim 1, wherein the converter is an edge-triggered counter.

3. The signal transmitting system of claim 1, wherein the first periodic signal consists of a periodic train of pulses.

4. The signal transmitting system of claim 3, wherein the restoring unit includes a first auto pulse generator configured to output a first pulse of the restored first periodic signal in response to a rising edge of the converted signal.

5. The signal transmitting system of claim 4, wherein the restoring unit further includes a second auto pulse generator configured to output a second pulse of the restored first periodic signal in response to a falling edge of the converted signal.

6. The signal transmitting system of claim 3, wherein the first periodic signal is a sense amplifier control signal.

7. The signal transmitting system of claim 3, wherein the first periodic signal is a precharge control signal.

8. A semiconductor memory device comprising:
a memory cell array including a plurality of memory cells arranged in a matrix, each having one access transistor and one storage capacitor;
a bit line sense amplifier connected to a bit line pair connected to a memory cell;
a local input/output line sense amplifier connected between a global input/output line pair and a local input/output line pair;
a column selecting unit operatively connecting the bit line pair and the local input/output line pair in response to a column selection signal;
a local input/output line precharge unit precharging the local input/output line pair during a period for which the column selection signal is deactivated;
a converter receiving a first sense amplifier control signal based on a clock signal, converting the first sense amplifier control signal into a converted control signal having a period two times the period of the clock signal, and outputting the converted control signal to a signal line; and
a restoring unit connected to the signal line, receiving the converted control signal, and restoring the first sense amplifier control signal from the converted control signal.

9. The semiconductor memory device of claim 8, wherein the converter is a positive edge-triggered counter.

10. The semiconductor memory device of claim 8, wherein the restoring unit includes a first auto pulse generator, configured to output a first pulse of the restored first sense amplifier control signal in response to a rising edge of the converted control signal.

11. The semiconductor memory device of claim 10, wherein the restoring unit includes a second auto pulse generator, including a plurality of inverters and a NAND gate, configured to output a second pulse of the restored first sense amplifier control signal in response to a falling edge of the converted control signal.

12. The semiconductor memory device of claim 8, wherein the first sense amplifier control signal is a sense amplifier control signal for controlling a local or global sense amplifier.

13. The semiconductor memory device of claim 8, wherein the first sense amplifier control signal is a precharge control signal for precharging the local or global input/output line pair.

14. A semiconductor device, comprising:
a control circuit configured to generate a periodic pulse train having a first period;
a bus line;
a converter receiving the periodic pulse train, converting the periodic pulse train into a clock signal that has a period two times the first period, and outputting the clock signal to the bus line; and
a restoring unit connected to the bus line, receiving the clock signal, and restoring the periodic pulse train from the clock signal.

15. The semiconductor device of claim 14, wherein the restoring unit includes:
a first auto pulse generator configured to output a first pulse of the restored periodic pulse train in response to a rising edge of the clock signal;
a second auto pulse generator configured to output a second pulse of the restored periodic pulse train in response to a falling edge of the clock signal; and
a combinatorial logic circuit configured to combine the output of the first auto pulse generator and the output of the second auto pulse generator, and to output the restored periodic pulse train.

16. The semiconductor device of claim 14, wherein the semiconductor device comprises a dynamic random access memory (DRAM).

17. The semiconductor device of claim 16, wherein the semiconductor device further comprises a microprocessing unit.

18. The semiconductor device of claim 17, wherein the semiconductor device further comprises a non-volatile memory.

19. The semiconductor device of claim 14, wherein the bus line is longer than 10000 microns.
